(19) United States
(12) Patent Application Publication
(10) Pub. No.: US 2026/0353596 A1
(43) Pub. Date: Nov. 5, 2026

(54) ADJUSTABLE AIRFLOW DUCT ASSEMBLY FOR ENHANCED COOLING EFFICIENCY

(71) Applicant: Aivres Systems Inc., San Jose, CA (US)

(72) Inventor: Cheng-Chan Chien, New Taipei City (TW)

(21) Appl. No.: 19/194,970

(22) Filed: Apr. 30, 2025

(51) Int. Cl. H05K 7/20

(52) U.S. Cl. CPC H05K 7/20145; H05K 7/20727

(57) ABSTRACT

An air duct assembly for a computing system is disclosed, designed to enhance cooling efficiency for high-power components. The assembly includes a duct body with at least one fixed air channel to direct airflow from a fan toward a first high-power component, such as a CPU or GPU. A window on the duct body houses a telescoping air channel (TAC) that extends to guide airflow to a second high-power component, such as a GPU, Host-Channel Adapter (HCA), or network interface card. When retracted, the TAC substantially blocks airflow through the window, ensuring airflow is concentrated in the fixed air channel.

### TECHNICAL FIELD

This invention relates to server cooling systems, specifically to the design and implementation of airflow ducts in server systems.

### BACKGROUND

In recent years, the demand for high-performance computing has driven significant advancements in server technology. The advent of artificial intelligence (AI), machine learning, and big data analytics has resulted in increasingly powerful server systems equipped with high-power components such as graphics processing units (GPUs), general-purpose GPUs (GPGPUs), and intelligent network interface cards (NICs). These components often exhibit high thermal energy density, necessitating advanced cooling mechanisms to ensure system stability and longevity.

Traditional server cooling systems primarily rely on air-cooling mechanisms, using built-in fans to direct airflow to critical components. To enhance the cooling efficiency of these systems, air ducts are often employed to guide and concentrate airflow to high-power heat-generating components such as CPUs and GPUs. However, existing air duct designs have notable limitations. They frequently increase system impedance, reduce overall airflow, and create localized turbulence, which diminishes their cooling effectiveness. Moreover, the compact form factor of certain servers imposes additional spatial constraints, further complicating the optimization of airflow paths.

In addition, high-power components located in the rear sections of server systems, such as GPUs and PCIe accelerator cards, often receive inadequate cooling due to these limitations. Traditional air ducts do not effectively address this challenge, resulting in overheating and potential system failures. Furthermore, designing and manufacturing different air ducts for different systems are cumbersome and costly.

There is a need for an innovative airflow duct design that can overcome these challenges by providing targeted cooling for high-power rear components, reducing airflow loss, and enabling easy installation and maintenance. The present invention addresses these issues by introducing an adjustable airflow duct with a quick-release mechanism, capable of enhancing cooling efficiency while maintaining energy efficiency and minimizing system complexity.

### SUMMARY

A system of one or more computers can be configured to perform specific operations or actions through the implementation of software, firmware, hardware, or a combination thereof. These configurations enable the system to execute tasks as programmed. Similarly, one or more computer programs can include instructions that, when executed by data processing apparatus, cause the apparatus to perform the desired actions.

In one general aspect, an air duct assembly is disclosed. The air duct assembly includes a duct body with at least one fixed air channel designed to receive airflow from a fan and direct it toward a first high-power component, such as a CPU or GPU, positioned near the front portion of a computing device. The air duct assembly also includes a window integrated into the duct body, and a telescoping air channel (TAC) disposed within the window. The TAC is extendable into the duct body to guide airflow to a second high-power component, such as a GPU, Host-Channel Adapter (HCA), network interface card, or another PCIe-based accelerator card located near the rear portion of the computing device. When retracted, the TAC substantially blocks airflow through the window, ensuring maximum airflow to the fixed air channel.

The air duct assembly may incorporate several innovative features. The TAC includes a gradual-tightening snap-fit mechanism or a corrugated flexible extension structure, which securely locks the TAC at one or more extended positions. The gradual-tightening snap-fit mechanism may include a series of tapered grooves or ridges on the outer surface of the TAC and complementary protrusions or detents on the window. The corrugated flexible extension structure may include a flexible, corrugated structure having a series of ridges and grooves, configured to allow the TAC to extend by expanding the corrugated structure and retract by collapsing the corrugated structure.

As the TAC extends, the frictional engagement between these features progressively increases, ensuring stable and precise positioning. When extended, the TAC forms a tapered air channel that accelerates the velocity of airflow inside it, delivering a concentrated stream of cool air to the second high-power component. The opening at the distal end of the TAC is smaller than the window opening, further focusing the airflow for improved cooling efficiency. When fully retracted, the TAC seals the window opening, forming a stable wall that withstands airflow pressure without deformation.

In one general implementation, a computing device may include a chassis, a fan for generating airflow, and the described air duct assembly. This configuration allows the system to dynamically direct airflow based on the thermal requirements of the components, improving overall cooling efficiency and reducing unnecessary airflow loss.

In another aspect, a method is disclosed for managing airflow in a computing device using the air duct assembly. The method includes receiving airflow from a fan into the fixed air channel of the duct body. It also involves extending the TAC to a length based on the thermal load of a rear-positioned high-power component. The TAC is locked into position using its gradual-tightening snap-fit mechanism or a corrugated flexible extension structure. When the rear-positioned component is absent or does not require intense cooling, the method includes retracting the TAC to substantially block the airflow through the window, ensuring airflow is directed to the front-positioned components.

The described air duct assembly, computing device, and method can be implemented through hardware, software, a method or process, or a computer-readable medium. These innovations offer improved thermal management for computing systems, particularly in environments with high-power components requiring precise and efficient cooling solutions.

### BRIEF DESCRIPTION OF THE DRAWINGS

Certain features of various embodiments of the present technology are set forth with particularity in the appended claims. A better understanding of the features and advantages of the technology will be obtained by reference to the following detailed description that sets forth illustrative embodiments, in which the principles of the disclosure are utilized, and the accompanying drawings of which:

FIG. 1 illustrates an adjustable airflow duct assembly with extendible and retractable telescoping air channel (TAC), in accordance with one embodiment.

FIG. 2 illustrates a front view of the adjustable airflow duct assembly, in accordance with one embodiment.

FIG. 3A illustrates the adjustable airflow duct assembly with the TAC in an extended state, in accordance with one embodiment.

FIG. 3B illustrates a front view of the TAC, in accordance with one embodiment.

FIG. 4 illustrates a front view of the adjustable airflow duct assembly with the TAC in an extended state, in accordance with one embodiment.

FIG. 5 illustrates a method of enhancing cooling efficiency using the adjustable airflow duct assembly, in accordance with one embodiment.

### DETAILED DESCRIPTION OF EMBODIMENTS

In the following description, certain specific details are set forth in order to provide a thorough understanding of various embodiments of the disclosure. However, one skilled in the art will understand that the disclosure may be practiced without these details. Moreover, while various embodiments of the disclosure are disclosed herein, many adaptations and modifications may be made within the scope of the disclosure in accordance with the common general knowledge of those skilled in this art. Such modifications include the substitution of known equivalents for any aspect of the disclosure in order to achieve the same result in substantially the same way.

Unless the context requires otherwise, throughout the present specification and claims, the word “comprise” and variations thereof, such as, “comprises” and “comprising” are to be construed in an open, inclusive sense, that is as “including, but not limited to.” Recitation of numeric ranges of values throughout the specification is intended to serve as a shorthand notation of referring individually to each separate value falling within the range inclusive of the values defining the range, and each separate value is incorporated in the specification as it were individually recited herein. Additionally, the singular forms “a,” “an” and “the” include plural referents unless the context clearly dictates otherwise.

Reference throughout this specification to “one embodiment” or “an embodiment” means that a particular feature, structure or characteristic described in connection with the embodiment is included in at least one embodiment of the present disclosure. Thus, the appearances of the phrases “in one embodiment” or “in an embodiment” in various places throughout this specification are not necessarily all referring to the same embodiment, but may be in some instances. Furthermore, the particular features, structures, or characteristics may be combined in any suitable manner in one or more embodiments.

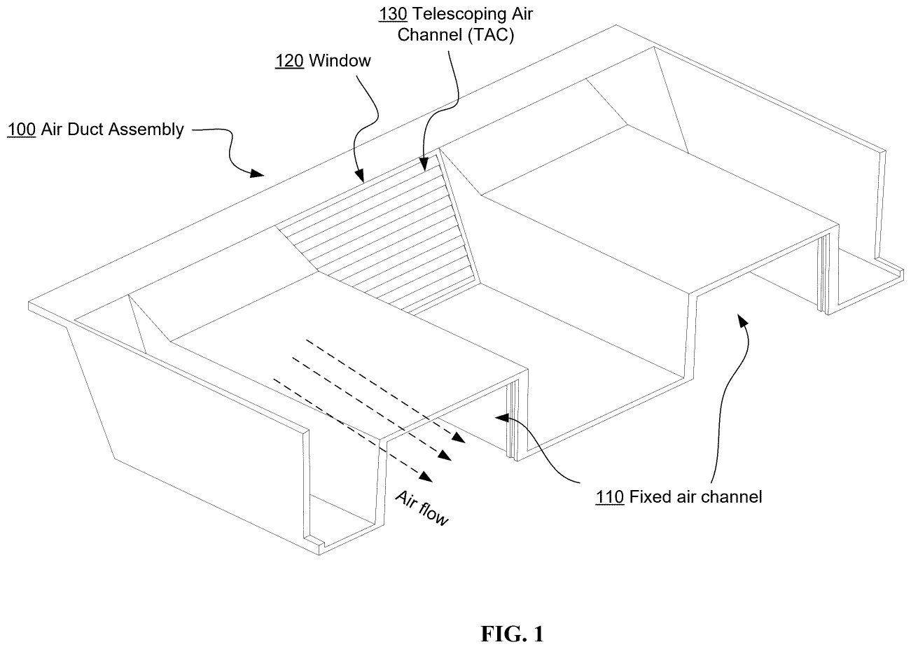

FIG. 1 illustrates an adjustable airflow duct assembly 100 with an extendable and retractable telescoping air channel (TAC) 130, in accordance with one embodiment. The air duct assembly 100 is designed for use in computing devices, such as servers, to efficiently cool high-power heat-generating components by optimizing the distribution of airflow within the device.

As shown in FIG. 1, the air duct assembly 100 includes at least one fixed air channel 110, which serves as a primary pathway for directing airflow from a fan toward high-power components located at the front end of the computing device. These components may include CPUs, GPUs, NPUs, or other heat-intensive processors that are typically positioned in the forward section of the chassis. The fixed air channel 110 ensures that these components receive a concentrated flow of cool air, improving thermal management for traditional server configurations.

The air duct assembly 100 further comprises a window 120 integrated into its structure and a telescoping air channel (TAC) 130 disposed within the window. The TAC 130 is designed to extend into the duct body when needed, creating a separate airflow path that delivers cool air directly to high-power components located at the rear of the computing device, such as GPUs, HCA cards, or PCIe accelerator cards. In its retracted state shown in FIG. 1, the TAC 130 may completely block the window 120 and prevent airflow from escaping through this opening, ensuring that the airflow is directed entirely through the fixed air channel 110. In some embodiments, the retracted TAC 130 may substantially, but not completely, block the window 120—a portion of the internal cavity remains partially open, forming a narrow slit, which allows a limited amount of air to continue passing through the slit. This design helps balance airflow distribution while maintaining the configurability of the air channel.

In the configuration illustrated in FIG. 1, the TAC 130 is in its retracted state. Airflow from the fan is directed exclusively through the fixed air channel 110, providing cooling to the front-end heat-generating components (e.g., the heat-generating components located closer to the outlet of the air channel 110 and reachable by cold air from the outlet of the air channel 110). This setup is well-suited for systems where the primary heat sources are located under or near the outlets of the fixed air channels.

The inclusion of the extendable and retractable TAC 130 provides additional flexibility to the air duct assembly 100, allowing it to dynamically adapt its internal airflow path. For instance, when extended, the TAC 130 forms an additional air channel that can direct airflow deeper into the system enclosure, accommodating systems with heat-generating, high-power components located toward the rear of the computing device (e.g., the components positioned farther away from the air inlet or air channel 110, such as GPUs or PCIe accelerator cards, or located in areas not adequately reached by the airflow from the air channel 110 due to physical layout or elevated upstream air temperature). This adaptable configuration enables more targeted cooling and broadens the applicability of the air duct assembly across a range of system layouts.

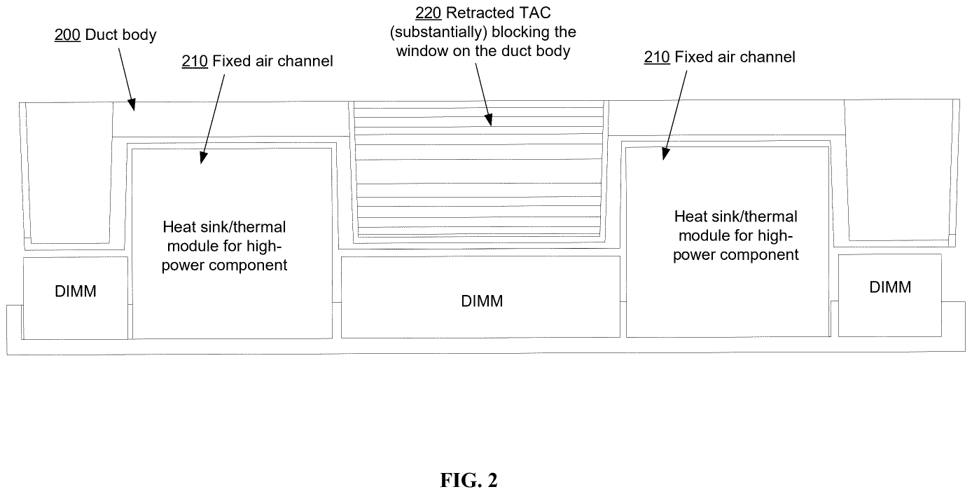

FIG. 2 illustrates a front view of the adjustable airflow duct assembly, in accordance with one embodiment. This illustration highlights how the duct body 200 of the airflow duct assembly is designed to optimize airflow distribution within the server system by concentrating the airflow through a fixed air channel 210. This configuration ensures that the majority of the airflow is directed to high-power heat-generating components, such as the CPU and GPU, which are typically coupled with a heat sink or thermal module for enhanced cooling.

In the embodiment shown, the fixed air channel 210 is positioned to align directly with these critical high-power heat-generating components, ensuring that the airflow from the fan reaches them efficiently. This targeted approach maximizes cooling performance for the front-end high-power components, which are the primary sources of heat in many traditional server configurations. The duct body 200 is structured to channel airflow away from low-power components, such as DIMMs, which generate significantly less heat and therefore do not require the same level of cooling.

FIG. 2 also illustrates the retracted telescoping air channel (TAC) 220, which blocks the airflow from passing through the window in the duct body 200. In this retracted state, the TAC ensures that the fixed air channel 210 receives the maximum possible airflow from the fan. This configuration is particularly effective where high-power components are concentrated at the front of the system and no significant heat sources are present near the rear of the system, i.e., the heat-generating components are located near to the outlets of the fixed air channel 210. Additionally, when the TAC is fully retracted into the window, it seals the window opening, forming a stable wall capable of withstanding the pressure of the airflow without deformation. This sealing function ensures that airflow remains directed through the fixed air channel while maintaining structural integrity under high-pressure conditions, enhancing the overall reliability and efficiency of the system.

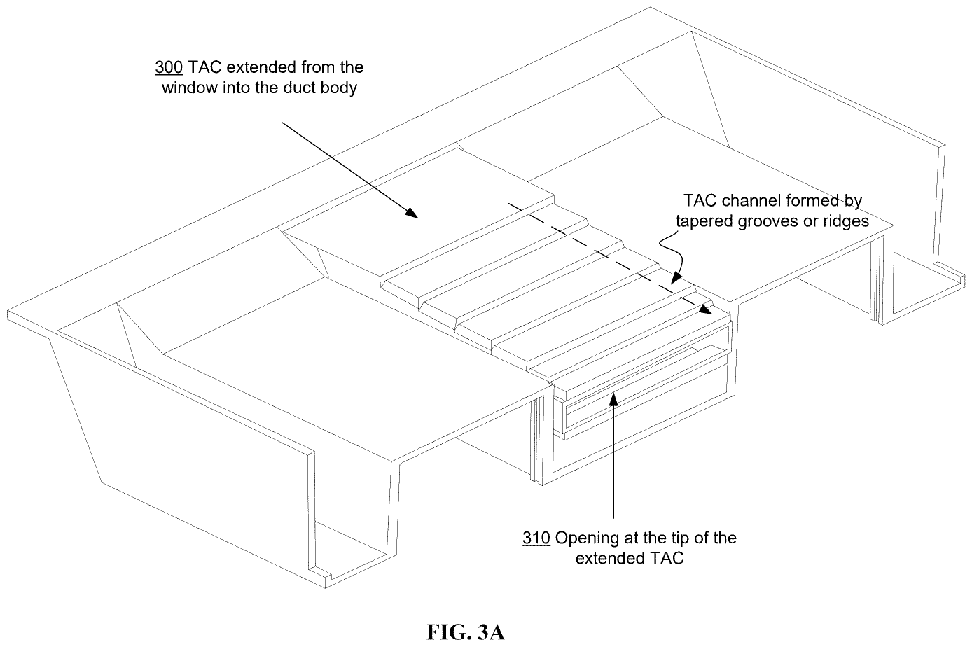

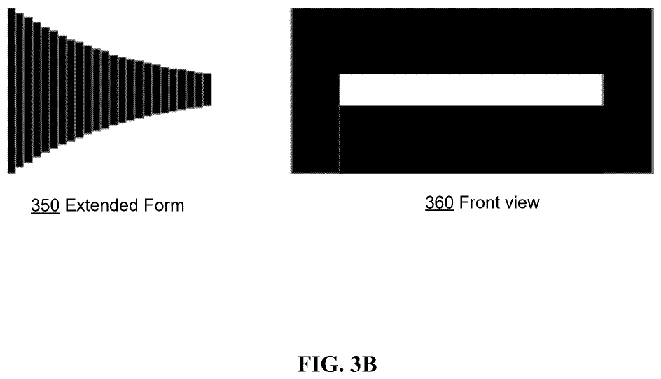

FIG. 3A illustrates the adjustable airflow duct assembly with the telescoping air channel (TAC) 300 in an extended state, in accordance with one embodiment. The TAC 300 is extended into the duct body, creating a new airflow path that allows cooling air to reach additional high-power components positioned near the rear portion of the computing system. At the distal end of the extended TAC 300, an opening 310 is formed, directing a targeted stream of airflow toward these components, which may include a GPU, a Host-Channel Adapter (HCA), a network interface card, or another PCIe-based accelerator card. In this configuration, the opening 310 forms an additional cooling target in additional to the fixed air channels.

In some embodiments, the TAC 300 uses a gradual-tightening snap-fit mechanism to securely lock the TAC in place at one or more extended positions. This snap-fit mechanism includes a series of tapered grooves or ridges formed along the outer surface of the TAC 300 and a corresponding set of complementary protrusions or detents integrated into the edges of the window through which the TAC extends. As the TAC is extended, the frictional engagement between these grooves and protrusions increases progressively, allowing the TAC to lock firmly in incremental extension lengths.

In some embodiments, the TAC 300 may be constructed using a flexible, corrugated telescoping structure similar to an expandable extension tube. In such embodiments, the TAC 300 includes a series of ridges and grooves along its length, forming a resilient body that can extend outward or compress inward along the airflow direction. When actuated, the corrugated structure allows the TAC 300 to stretch by pulling the ridged sections apart and to retract by collapsing the ridged sections together. The corrugated structure may provide some inherent frictional resistance to maintain the TAC 300 at a selected length, without relying on discrete locking positions.

When the TAC 300 is in its extended position, it also forms a tapered air channel that receives the airflow through the window and accelerates the velocity of the airflow within that channel. By gradually narrowing toward the distal opening, the TAC focuses the air stream, creating a higher-velocity airflow that is directed precisely at high-power components situated near the rear portion of the computing system. This targeted approach to airflow not only increases cooling efficiency but also helps to prevent unnecessary turbulence and airflow loss, contributing to a more efficient overall cooling strategy.

FIG. 3B illustrates a front view of the telescoping air channel (TAC), in accordance with one embodiment. As shown in FIG. 3B, the TAC is depicted in its extended form 350, along with a front view 360 of the TAC. In this embodiment, the front view 360 remains the same regardless of whether the TAC is in the retracted or extended state. Specifically, the TAC includes an internal cavity or center slit that remains open at all times. Thus, even when the TAC is retracted, the center slit permits a limited amount of airflow through the air duct assembly. The retracted TAC substantially, but not completely, blocks the airflow, while the extended TAC directs airflow more effectively toward deeper regions of the system to cool high-power components. At the same time, the retracted TAC forms a stable structure capable of withstanding airflow pressure without significant deformation.

In some embodiments, the TAC can be automatically controlled to extend or retract based on the system configuration. For example, the system may include a detection mechanism configured to determine whether a PCIe card, GPU card, or other high-power device has been installed in a corresponding expansion slot near the rear portion of the computing device.

In one embodiment, the detection mechanism may leverage existing system hardware and firmware, such as PCIe slot presence detection circuitry, hot-plug detection signals, or signals monitored by a system management controller (e.g., a Baseboard Management Controller (BMC)). When a card insertion is detected through existing infrastructure, a detection signal may be transmitted to a controller associated with the air duct assembly. The controller, upon receiving the detection signal, may actuate the TAC to move from its retracted position to its extended position, thereby creating a dedicated airflow path toward the newly installed high-power component.

In another embodiment, the air duct assembly may include its own local detection module. The local detection module may be, for example, a mechanical micro-switch positioned adjacent to the expansion slot, an optical sensor configured to detect the physical presence of an inserted card, a magnetic sensor (such as a reed switch), or another suitable sensing device. Upon detecting the insertion of a card, the local detection module generates a detection signal that is transmitted to the TAC controller to actuate extension of the TAC.

In some implementations, the actuation of the TAC can be achieved through a mechanical drive mechanism, such as an electric motor, a solenoid actuator, or a spring-assisted deployment system. In one embodiment, the TAC may be constructed using a corrugated, telescoping structure similar to a flexible extension tube. The TAC includes a series of ridges and grooves along its length, forming a resilient and extendable body that can stretch outward or compress inward along the airflow direction. When actuated, the corrugated structure allows the TAC to extend by pulling the ridged sections apart, and retract by collapsing the ridged sections back together.

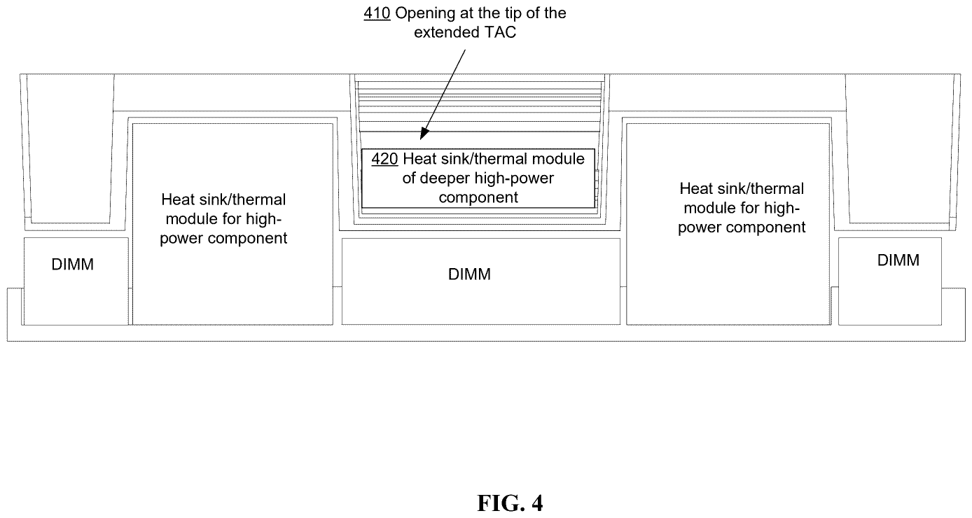

FIG. 4 illustrates a front view of the adjustable airflow duct assembly with the telescoping air channel (TAC) in an extended state, in accordance with one embodiment. In this configuration, the TAC extends into the duct body, forming an additional airflow path that specifically targets high-power components located deeper within the system. In some embodiments, the TAC is a hollow, telescoping structure. When extended, the TAC slides outward and reveals its internal cavity, with an open distal end configured to direct airflow. This transformation allows the TAC to shift from acting as a simple wall to becoming a functional air conduit. By extending the TAC toward the rear of the device, the system ensures that these components, which are often overlooked in traditional designs, receive a direct supply of cool air.

As used herein, the “rear” of the device refers to regions containing components that are either positioned farther away from the air inlet or air channel 110—such as GPUs or PCIe accelerator cards—or located in areas not adequately reached by airflow from the air channel 110 due to system layout or the presence of elevated upstream air temperature.

In some embodiments, the transition between the retracted and extended modes may be performed manually or automatically. For example, in certain implementations, the TAC may extend in response to a detected rise in temperature of a nearby high-power component, thereby dynamically adjusting the airflow path to meet the system's thermal demands. In other implementations, the TAC may be preconfigured to remain in either the retracted mode or the extended mode based on the physical layout of the heat-generating components in the system.

Even though FIG. 4 shows the TAC extending to approximately the same depth as the fixed air channels, a person of ordinary skill in the art would understand that the TAC may be implemented and configured to extend to and locked with a desired depth within the duct. For example, the TAC may be extended deeper than the fixed air channel if high-power components are located farther down in the system, or configured to extend a shorter distance if additional heat-generating components are positioned between the fixed air channels (e.g., outside an airflow path directed by the outlet of the air channels). This flexibility enables tailored airflow delivery to specific thermal zones within a variety of system layouts.

From the front view, it can be seen that an opening 410 at the distal end of the TAC channels airflow to heat sinks or thermal modules 420 associated with the deeper high-power components. In a traditional design, by the time the air passes through the fixed air channels and reaches the system's rear sections, it has already absorbed heat from the front-end components, effectively becoming hot air. This reduced cooling capacity can lead to inadequate thermal management and potential overheating in the rear components. However, with the TAC extended and directing fresh airflow through the opening 410, these components can be cooled more efficiently, mitigating temperature build-up and improving the overall thermal performance of the system.

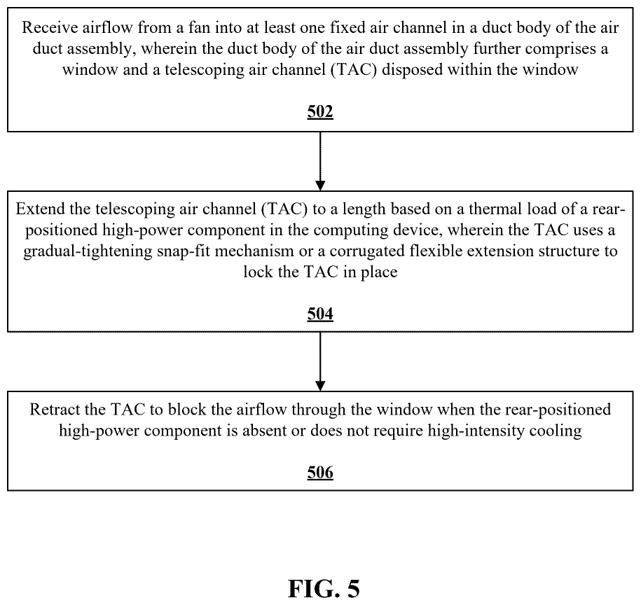

FIG. 5 illustrates a process 500 of enhancing cooling efficiency using the adjustable airflow duct assembly, in accordance with one embodiment. In some implementations, the steps of process 500 may be performed by using the air duct assembly described in FIGS. 1-4.

At block 502, the process begins with receiving airflow from a fan into at least one fixed air channel in the duct body of the air duct assembly. The duct body also includes a window and a telescoping air channel (TAC) disposed within the window. The fixed air channel directs airflow to front-positioned high-power components such as CPUs or GPUs, while the window and TAC enable dynamic airflow control for additional components.

At block 504, the process includes extending the TAC to a length determined by the thermal load of a rear-positioned high-power component, such as a GPU, Host-Channel Adapter (HCA), or PCIe accelerator card. The TAC includes a gradual-tightening snap-fit mechanism or a corrugated flexible extension structure, which securely locks the TAC at one or more extended positions. The gradual-tightening snap-fit mechanism may include a series of tapered grooves or ridges on the outer surface of the TAC and complementary protrusions or detents on the window. The corrugated flexible extension structure may include a flexible, corrugated structure having a series of ridges and grooves, configured to allow the TAC to extend by expanding the corrugated structure and retract by collapsing the corrugated structure.

At block 506, the process involves retracting the TAC fully into the window when the rear-positioned high-power component is absent or does not require intense cooling. When retracted, the TAC substantially closes the window while leaving an internal cavity open to permit limited airflow through a center slit, and forms a stable structure capable of withstanding pressure from the airflow without significant deformation.

Process 500 may also include additional implementations or variations.

In some embodiments, the gradual-tightening snap-fit mechanism and the corrugated flexible extension structure enable secure locking of the TAC at incremental extension lengths, providing flexibility for targeted cooling.

When the TAC is extended, it forms a tapered air channel that accelerates the airflow and directs a concentrated stream through its distal opening to cool rear-positioned components efficiently.

When the TAC is fully retracted, it seals the window, ensuring that airflow is concentrated through the fixed air channels and preventing unnecessary airflow loss.

The foregoing description of the present disclosure has been provided for the purposes of illustration and description. It is not intended to be exhaustive or to limit the disclosure to the precise forms disclosed. The breadth and scope of the present disclosure should not be limited by any of the above-described exemplary embodiments. Many modifications and variations will be apparent to the practitioner skilled in the art. The modifications and variations include any relevant combination of the disclosed features. The embodiments were chosen and described in order to best explain the principles of the disclosure and its practical application, thereby enabling others skilled in the art to understand the disclosure for various embodiments and with various modifications that are suited to the particular use contemplated. It is intended that the scope of the disclosure be defined by the following claims and their equivalence.

What is claimed is:

1. An air duct assembly for a computing system, comprising:
a duct body comprising at least one fixed air channel configured to receive airflow from a fan and direct the airflow toward a first high-power component;
a window formed on the duct body; and
a telescoping air channel (TAC) disposed within the window, the TAC being extendable into the duct body to guide the airflow to a second high-power component and retractable to substantially block the airflow through the window when retracted.

2. The air duct assembly of claim 1, wherein the second high-power component is positioned either farther from, or outside an airflow path directed by, an outlet of the at least one fixed air channel.

3. The air duct assembly of claim 1, wherein the second high-power component comprises a GPU, a Host-Channel Adapter (HCA), a network interface card, or another PCIe-based accelerator card.

4. The air duct assembly of claim 1, wherein the first high-power component is positioned close to an outlet of the at least one fixed air channel, and comprises a CPU or a GPU.

5. The air duct assembly of claim 1, wherein the TAC further comprises a gradual-tightening snap-fit mechanism or a corrugated flexible extension structure, configured to lock the TAC securely at one or more extended positions and thereby maintain a stable airflow path for targeted cooling.

6. The air duct assembly of claim 5, wherein the gradual-tightening snap-fit mechanism comprises:
a series of tapered grooves or ridges formed on an outer surface of the TAC; and
a corresponding set of complementary protrusions or detents on the window,
such that frictional engagement between the TAC and the window increases progressively, allowing the TAC to lock at incremental extension lengths.

7. The air duct assembly of claim 5, wherein the corrugated flexible extension structure comprises:
a flexible, corrugated structure having a series of ridges and grooves, configured to allow the TAC to extend by expanding the corrugated structure and retract by collapsing the corrugated structure.

8. The air duct assembly of claim 1, wherein the TAC, when extended into the duct body, leaves an opening at a distal end of the TAC, directing a targeted stream of airflow to the second high-power component through the opening.

9. The air duct assembly of claim 8, wherein the opening at the distal end of the TAC has a smaller size than a size of the window.

10. The air duct assembly of claim 1, wherein the TAC, when retracted fully into the window, substantially closes the window while leaving an internal cavity open to permit limited airflow through a center slit, and forms a stable structure capable of withstanding pressure from the airflow without significant deformation.

11. The air duct assembly of claim 1, wherein the TAC, when extended, forms a tapered air channel that receives the airflow through the window, accelerating a velocity of the airflow inside the tapered air channel.

12. A computing device, comprising:
a chassis;
a fan for generating an airflow through the chassis; and
an air duct assembly that comprises:
a duct body comprising at least one fixed air channel configured to receive airflow from the fan and direct the airflow toward a first high-power component in the chassis;
a window formed on the duct body; and
a telescoping air channel (TAC) disposed within the window, the TAC being extendable into the duct body to guide the airflow to a second high-power component in the chassis and retractable to substantially block the airflow through the window when retracted.

13. The computing device of claim 12, wherein the TAC further comprises a gradual-tightening snap-fit mechanism, configured to lock the TAC securely at one or more extended positions and thereby maintain a stable airflow path for targeted cooling, and the gradual-tightening snap-fit mechanism comprises:
a series of tapered grooves or ridges formed on an outer surface of the TAC; and
a corresponding set of complementary protrusions or detents on the window,
such that frictional engagement between the TAC and the window increases progressively, allowing the TAC to lock at incremental extension lengths.

14. The computing device of claim 12, wherein the TAC further comprises a corrugated flexible extension structure, configured to lock the TAC securely at one or more extended positions and thereby maintain a stable airflow path for targeted cooling, and the corrugated flexible extension structure comprises:
a flexible, corrugated structure having a series of ridges and grooves, configured to allow the TAC to extend by expanding the corrugated structure and retract by collapsing the corrugated structure.

15. The computing device of claim 12, wherein the TAC, when extended into the duct body, leaves an outlet at a distal end of the TAC, directing a targeted stream of airflow to the second high-power component through the outlet.

16. The computing device of claim 12, wherein the TAC, when retracted fully into the window, seals the window opening, forming a stable wall to withstand a pressure of the airflow without deformation.

17. The computing device of claim 12, wherein the TAC, when extended, forms a tapered air channel that receives the airflow through the window, accelerating a velocity of the airflow inside the tapered air channel.

18. A method of adjusting airflow in a computing device equipped with an air duct assembly, the method comprising:
receiving airflow from a fan into at least one fixed air channel in a duct body of the air duct assembly, wherein the air duct assembly further comprises a window and a telescoping air channel (TAC) disposed within the window;
extending the telescoping air channel (TAC) to a length based on a thermal load of a rear-positioned high-power component in the computing device, wherein the TAC uses a gradual-tightening snap-fit mechanism or a corrugated flexible extension structure to lock the TAC in place; and
retracting the TAC to substantially block the airflow through the window when the rear-positioned high-power component is absent or does not require high-intensity cooling.

19. The method of claim 18, wherein retracking the TAC fully into the window seals the window opening, forming a stable wall to withstand a pressure of the airflow without deformation.

20. The method of claim 18, wherein the TAC, when extended, forms a tapered air channel that receives the airflow through the window, accelerating a velocity of the airflow inside the tapered air channel.
